(19) United States
(12) Patent Application Publication
(10) Pub. No.: US 2023/0393386 A1
(43) Pub. Date: Dec. 7, 2023

(54) DRIVE ELEMENT AND LIGHT DEFLECTION ELEMENT

(71) Applicant: Panasonic Intellectual Property Management Co., Ltd., Osaka (JP)

(72) Inventor: Kensuke MIHARA, Osaka (JP)

(21) Appl. No.: 18/235,708

(22) Filed: Aug. 18, 2023

Related U.S. Application Data
(63) Continuation of application No. PCT/JP22/03591, filed on Jan. 31, 2022.

(30) Foreign Application Priority Data
Feb. 22, 2021 (JP) 2021-025988

(51) Int. Cl. G02B 26/10; H02N 2/12

(52) U.S. Cl. CPC G02B 26/10; H02N 2/12

(57) ABSTRACT

A drive element includes: a pair of drive parts placed so as to be aligned in one direction; a movable part placed between the pair of drive parts; a pair of support parts placed such that the pair of drive parts and the movable part are interposed therebetween; a pair of connection parts connecting the pair of support parts to the movable part; and a fixing part connected to at least each of the pair of drive parts in an alignment direction of the pair of drive parts. Both end portions of the pair of support parts are connected to the pair of drive parts, respectively, and gaps each having a predetermined length are provided between the pair of support parts and the pair of drive parts so as to extend in the alignment direction of the pair of drive parts.

### CROSS REFERENCE TO RELATED APPLICATION

This application is a continuation of International Application No. PCT/JP2022/003591 filed on Jan. 31, 2022, entitled “DRIVE ELEMENT AND LIGHT DEFLECTION ELEMENT”, which claims priority under 35 U.S.C. Section 119 of Japanese Patent Application No. 2021-025988 filed on Feb. 22, 2021, entitled “DRIVE ELEMENT AND LIGHT DEFLECTION ELEMENT”. The disclosures of the above applications are incorporated herein by reference.

### BACKGROUND OF THE INVENTION

### Field of the Invention

The present invention relates to a drive element that rotates a movable part about a rotation axis, and a light deflection element using the drive element.

### Description of Related Art

In recent years, by using micro electro mechanical system (MEMS) technology, drive elements that rotate a movable part have been developed. In this type of drive element, a reflection surface is located on the movable part, thereby allowing scanning to be performed at a predetermined deflection angle with light incident on the reflection surface. This type of drive element is installed in image display devices such as head-up displays and head-mounted displays. In addition, this type of drive element can also be used in laser radars that use laser beams to detect objects, etc.

“Shanshan Gu-Stoppel, Thorsten Giese, Hans-Joachim Quenzer, Ulrich Hofmann and Wolfgang Benecke, ‘PZT-Actuated and—Sensed Resonant Micromirrors with Large Scan Angles Applying Mechanical Leverage Amplification for Biaxial Scanning’, Micromachines, issued in 2017, Vol. 8, Issue 7, P215” describes a drive element that rotates a mirror about a rotation axis by driving a pair of support parts parallel to each other. In the drive element, a drive part is placed at each of both ends of the pair of support parts. Both ends of the pair of support parts are driven up and down by these drive parts. Accordingly, torsion is generated at a connection part connecting the middles of the pair of support parts, so that a movable part located at the center of the connection part rotates. Thus, a mirror placed on the movable part rotates about the rotation axis defined by the connection part.

The drive element configured as described above has a simple configuration and thus can be easily formed. However, in the drive element, the rotation angle of the movable part per 1 Vpp is small, so that further improvement of the driving efficiency of the movable part is required.

### SUMMARY OF THE INVENTION

A first aspect of the present invention is directed to a drive element. The drive element according to this aspect includes: a pair of drive parts placed so as to be aligned in one direction; a movable part placed between the pair of drive parts; a pair of support parts placed such that the pair of drive parts and the movable part are interposed therebetween; a pair of connection parts connecting the pair of support parts to the movable part; and a fixing part connected to at least each of the pair of drive parts in an alignment direction of the pair of drive parts. Both end portions of the pair of support parts are connected to the pair of drive parts, respectively. Gaps each having a predetermined length are provided between the pair of support parts and the pair of drive parts so as to extend in the alignment direction of the pair of drive parts.

In the drive element according to this aspect, since the pair of support parts and the pair of drive parts are separated from each other by the gaps, curving of support parts at the positions of the gaps is not inhibited by the drive parts. In addition, the driving force of each drive part generated around each gap is transmitted to the support part via the connection range other than the gap. Therefore, the support parts can be more efficiently driven by the drive parts, so that the driving efficiency of the movable part can be increased.

A second aspect of the present invention is directed to a light deflection element. The light deflection element according to this aspect includes the drive element according to the first aspect and a reflection surface located on the movable part.

Since the light deflection element according to this aspect includes the drive element according to the first aspect, the driving efficiency of the movable part can be increased. Therefore, the driving efficiency of the reflection surface can be increased, so that deflection of and scanning with light can be performed at a higher deflection angle.

The effects and the significance of the present invention will be further clarified by the description of the embodiment below. However, the embodiment below is merely an example for implementing the present invention. The present invention is not limited to the description of the embodiment below in any way.

### BRIEF DESCRIPTION OF THE DRAWINGS

FIG. 1 is a perspective view showing a configuration of a drive element according to an embodiment;

FIG. 2A is a plan view showing the configuration of the drive element according to the embodiment;

FIG. 2B is a plan view showing a configuration of a drive element according to a comparative example;

FIG. 3A shows a simulation result, obtained by simulation, of a driving state of each part when a movable part according to the embodiment is at a maximum deflection angle position;

FIG. 3B shows a simulation result, obtained by simulation, of a driving state of each part when a movable part according to the comparative example is at a maximum deflection angle position;

FIG. 4A is a graph showing a simulation result of examining the displacement of each of the positions of a support part and a drive part during driving according to the embodiment;

FIG. 4B is a graph showing a simulation result of examining the displacement of each of the positions of a support part and a drive part during driving according to the comparative example;

FIG. 5 is a plan view showing a configuration used for examining an inflection point of the support part according to the embodiment;

FIG. 6A is a graph showing a simulation result of a displacement distribution of the support part in a vibration direction according to the embodiment;

FIG. 6B is a graph showing the gradient of a waveform of the displacement distribution obtained by differentiating the graph in FIG. 6A according to the embodiment; and

FIG. 7 shows a simulation result showing a relationship between the depth of each slit and the driving efficiency of the movable part according to the embodiment.

It should be noted that the drawings are solely for description and do not limit the scope of the present invention by any degree.

### DETAILED DESCRIPTION

Hereinafter, an embodiment of the present invention will be described with reference to the drawings. For convenience, in each drawing, X, Y, and Z axes that are orthogonal to each other are additionally shown. The Y-axis direction is a direction parallel to a rotation axis of a drive element, and the Z-axis direction is a direction perpendicular to a reflection surface located on a movable part.

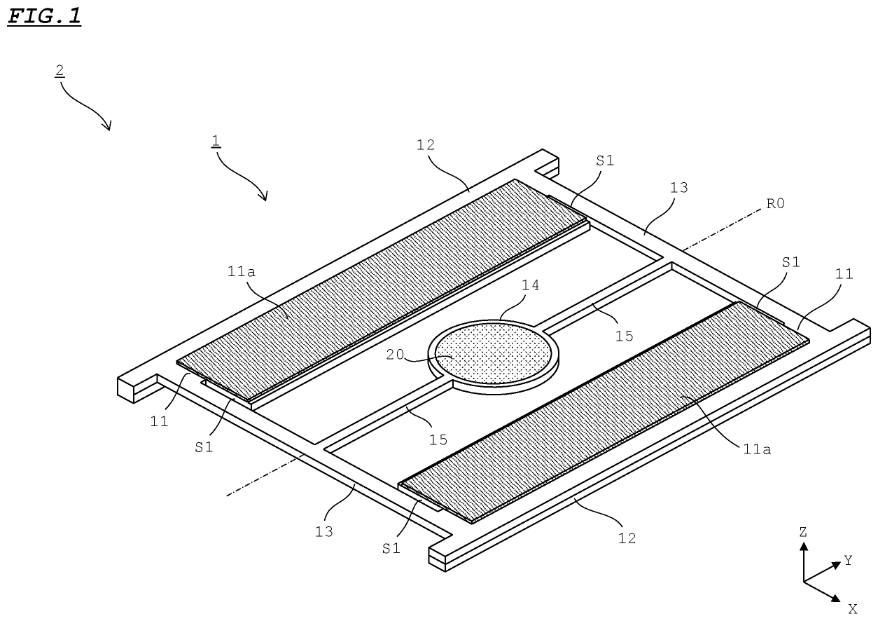

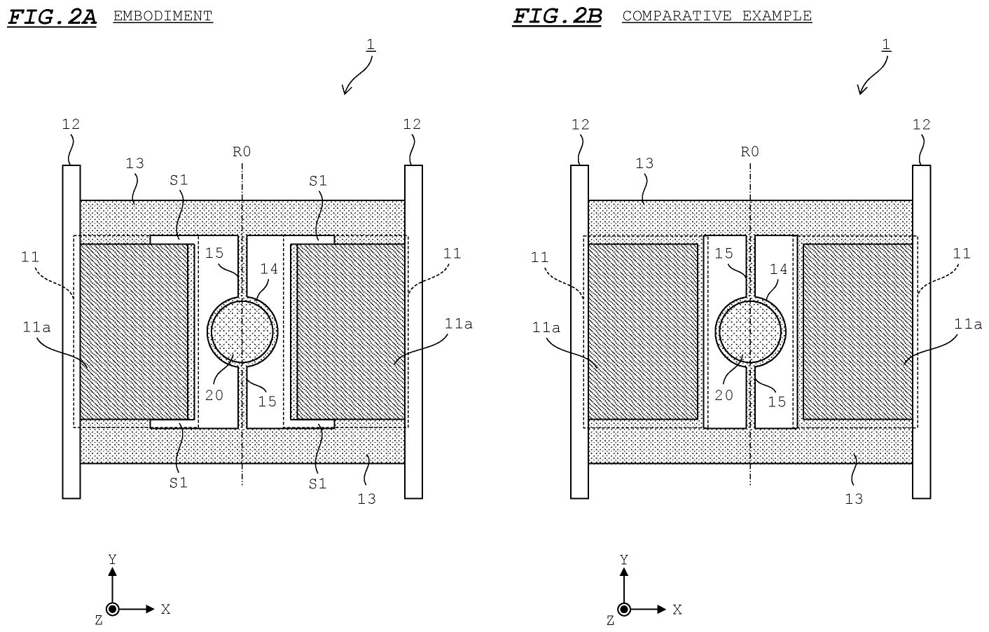

FIG. 1 is a perspective view showing a configuration of a drive element 1, and FIG. 2A is a plan view showing the configuration of the drive element 1.

As shown in FIG. 1 and FIG. 2A, the drive element 1 includes a pair of drive parts 11, a pair of fixing parts 12, a pair of support parts 13, a movable part 14, and a pair of connection parts 15. A reflection surface 20 is located on the upper surface of the movable part 14, whereby a light deflection element 2 is configured. The drive element 1 has a symmetrical shape in the X-axis direction and the Y-axis direction in a plan view.

The pair of drive parts 11 are placed so as to be aligned in the X-axis direction. In a plan view, the shapes and the sizes of the pair of drive parts 11 are the same as each other. The shape of each drive part 11 is a rectangular shape in a plan view in the case where no slit S1 is formed therein. The pair of drive parts 11 are placed such that ends on the inner side (movable part 14 side) thereof are parallel to the Y axis.

The pair of fixing parts 12 are placed such that the pair of drive parts 11 are interposed therebetween in the X-axis direction. The pair of fixing parts 12 have a constant width in the X-axis direction and extend parallel to the Y-axis direction. The drive element 1 is installed on an installation surface by installing the fixing parts 12 on the installation surface. The inner boundaries of the pair of fixing parts 12 are connected to the outer boundaries of the pair of drive parts 11 and the pair of support parts 13.

The pair of support parts 13 are placed such that the pair of drive parts 11 and the movable part 14 are interposed therebetween in the Y-axis direction. The pair of support parts 13 have a constant width in the Y-axis direction and extend parallel to the X-axis direction. The outer boundaries of the pair of support parts 13 are connected to the inner boundaries of the pair of fixing parts 12. In addition, end portions on both sides in the X-axis direction of the pair of support parts 13 are connected to the boundaries in the Y-axis direction of the pair of drive parts 11.

The movable part 14 is placed between the pair of drive parts 11. In the Y-axis direction, the center position of the movable part 14 coincides with the middle positions of the pair of drive parts 11. In the X-axis direction, the center position of the movable part 14 coincides with the middle positions of the pair of support parts 13. Here, the shape of the movable part 14 is a circular shape in a plan view. The shape of the movable part 14 in a plan view may be a shape other than a circular shape, such as a square shape. The reflection surface is located on the upper surface of the movable part 14. The reflection surface 20 is located on the upper surface of the movable part 14, for example, by forming a reflection film thereon by vapor deposition or the like. The reflection surface may be formed by subjecting the upper surface of the movable part 14 to mirror finish.

The pair of connection parts 15 connect the pair of support parts 13 to the movable part 14. The pair of connection parts 15 extend in a straight manner from the middle positions in the X-axis direction of the pair of support parts 13 toward the movable part 14 and are connected to the middle position in the X-axis direction of the movable part 14. The widths in the X-axis direction of the pair of connection parts 15 are constant. The lengths in the Y-axis direction of the pair of connection parts 15 are equal to each other. A cross-sectional shape of each connection part 15 when the connection part 15 is cut along a plane parallel to the X-Z plane is a rectangular shape whose upper side is parallel to the X-Y plane.

A slit S1 is formed at each of both ends in the Y-axis direction of the pair of drive parts 11. The slits S1 are formed so as to extend outward from the ends on the inner side (movable part 14 side) of the pair of drive parts 11 by a predetermined length (depth). The slits S1 are formed by cutting the pair of drive parts 11 in a straight line from the ends on the inner side of the drive parts 11 toward the outer side. The widths and the lengths (depths) of the four slits S1 are equal to each other. Gaps are formed between the drive parts 11 and the support parts 13 by the four slits S1. The drive parts 11 and the support parts 13 are separated from each other by the gaps.

Piezoelectric drivers 11a are placed on the upper surfaces of the pair of drive parts 11. That is, the pair of drive parts 11 each include the piezoelectric driver 11a as a drive source. In a plan view, each piezoelectric driver 11a has a rectangular shape. The width of the piezoelectric driver 11a in the Y-axis direction is equal to the width in the Y-axis direction of a portion, of the drive part 11, interposed between the two slits S1. In addition, the outer boundary of the piezoelectric driver 11a coincides with the inner boundary of the fixing part 12.

The piezoelectric driver 11a has a lamination structure in which electrode layers are placed on the upper and lower sides of a piezoelectric thin film having a predetermined thickness, respectively. The piezoelectric thin film is made of, for example, a piezoelectric material having a high piezoelectric constant, such as lead zirconate titanate (PZT). The electrode layers are made of a material having low electrical resistance and high heat resistance, such as platinum (Pt). The piezoelectric driver 11a is placed by forming the lamination structure, which includes the piezoelectric thin film and the electrode layers on the upper and lower sides thereof, on the upper surface of a substrate included in the region of the piezoelectric driver 11a by a sputtering method or the like.

A substrate of the drive element 1 has the same contour as the drive element 1 in a plan view, and has a constant thickness. The reflection surface 20 and the piezoelectric drivers 11a are placed in corresponding regions of the upper surface of the substrate. The thicknesses of the fixing parts 12 are increased by further stacking a predetermined material on the lower surfaces of portions, of the substrate, corresponding to the fixing parts 12. The material stacked at the fixing parts 12 may be a material different from that of the substrate, or may be the same material as that of the substrate.

The substrate is, for example, integrally formed from silicon or the like. However, the material forming the substrate is not limited to silicon, and may be another material. The material forming the substrate is preferably a material having high mechanical strength and Young's modulus, such as metal, crystal, glass, and resin. As such a material, in addition to silicon, titanium, stainless steel, Elinvar, a brass alloy, etc., can be used. The same applies to the material stacked on the substrate at each fixing part 12.

The pair of drive parts 11 are curved in the Z-axis direction when a drive signal is supplied from a drive circuit which is not shown to the piezoelectric drivers 11a. Accordingly, the pair of support parts 13 are curved in the Z-axis direction. As a result, the connection parts 15 are twisted around a rotation axis R0, and the movable part 14 rotates about the rotation axis R0. Accordingly, the reflection surface 20 rotates about the rotation axis R0.

The reflection surface 20 reflects light incident thereon from above the movable part 14, in a direction corresponding to a deflection angle of the movable part 14. Accordingly, the light (e.g., laser beam) incident on the reflection surface 20 is deflected and scanning is performed with this light as the movable part 14 rotates.

In the present embodiment, as described above, the slits S1 each having a predetermined length (depth) are formed near the boundaries between the pair of drive parts 11 and the pair of support parts 13, and the pair of drive parts 11 and the pair of support parts 13 are separated from each other at the positions of these slits S1. Accordingly, the driving efficiency of the movable part 14 and the reflection surface 20 can be made higher than that in the case where these slits S1 are not formed.

FIG. 2B is a plan view showing a configuration example (comparative example) of the drive element 1 in the case where no slit S1 is formed. In the comparative example, the inner boundary of each drive part 11 extends to the inner boundaries of the pair of support parts 13 and is connected to the support parts 13.

The inventor confirmed that in the configuration of the comparative example in FIG. 2B, the rotation angle of the movable part 14 per 1 Vpp is small, and thus the reflection surface 20 cannot be rotated efficiently during light scanning. As a result of an intensive study, the inventor newly found that the driving efficiency of the movable part 14 can be increased by adding a simple configuration of forming the slits S1 (gaps) near the boundaries between the pair of drive parts 11 and the pair of support parts 13 as shown in FIG. 1 and FIG. 2A.

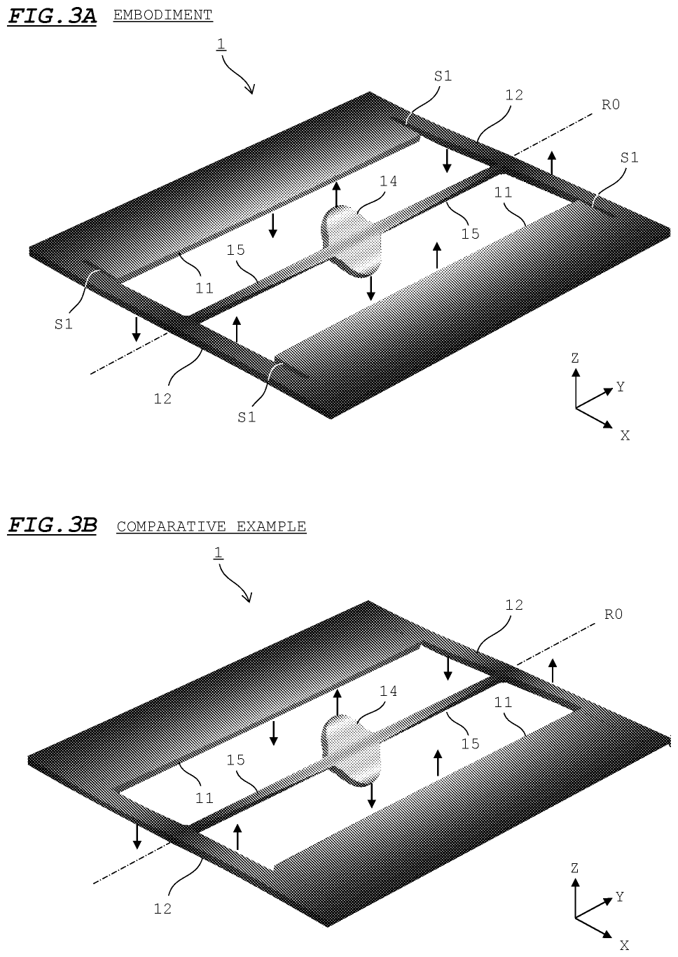

FIG. 3A shows a simulation result, obtained by simulation, of a driving state of each part when the movable part according to the embodiment is at a maximum deflection angle position. FIG. 3B shows a simulation result, obtained by simulation, of a driving state of each part when the movable part according to the comparative example is at a maximum deflection angle position.

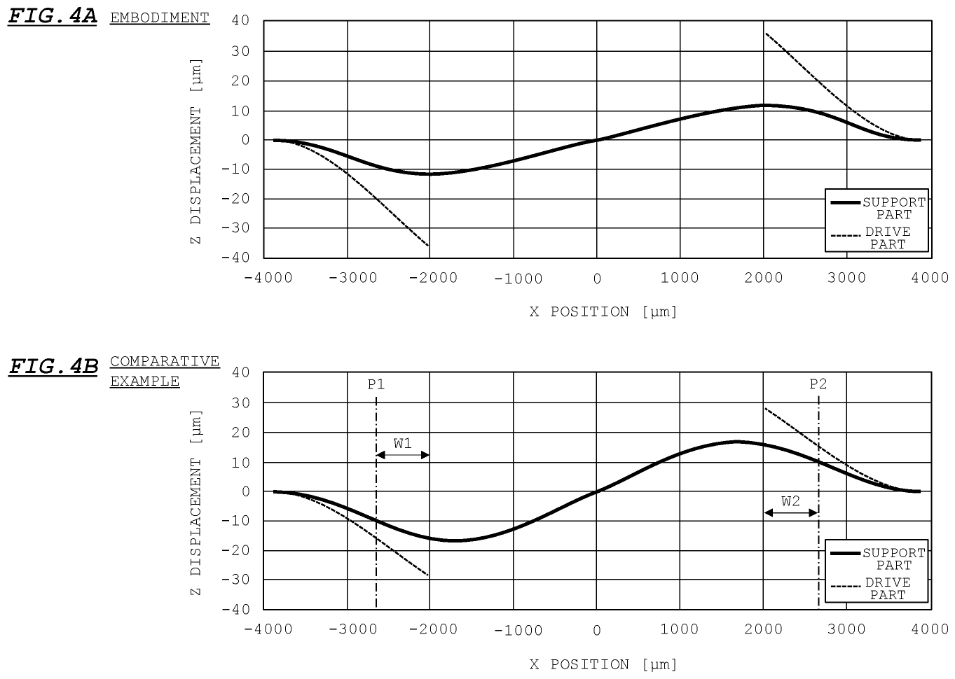

As shown in FIGS. 3A and 3B, in each of the configurations of the embodiment and the comparative example, the pair of drive parts 11 are driven in directions opposite to each other, whereby the pair of support parts 13 are curved in opposite directions with the connection positions of the pair of connection parts 15 as boundaries. Accordingly, the pair of connection parts 15 are twisted around the rotation axis R0. Due to this twisting, the movable part 14 rotates about the rotation axis R0. As can be seen by comparing FIGS. 4A and 4B, in the configuration of the embodiment, by providing the slits S1, the drive parts 11 vibrate more greatly than in the comparative example. Arrows in FIGS. 3A and 3B indicate the displacement direction of each part.

FIG. 4A is a graph showing a simulation result of examining the displacement of each of the positions of the support part 13 and the drive part 11 during driving according to the embodiment. FIG. 4B is a graph showing a simulation result of examining the displacement of each of the positions of the support part 13 and the drive part 11 during driving according to the comparative example. FIGS. 4A and 4B show the waveforms of the support part 13 and the drive part 11 when the support part 13 vibrates to the highest degree.

In FIGS. 4A and 4B, the horizontal axis shows the position in the X-axis direction (separation distance from the rotation axis R0) in the case where the position of the rotation axis R0 is defined as 0. Here, a position in the X-axis positive direction is indicated by a positive value, and a position in the X-axis negative direction is indicated by a negative value. The vertical axis shows the amount of displacement in the Z-axis direction in the case where the positions of the drive part 11 and the support part 13 when not curved (in a horizontal state) are defined as 0. The amount of displacement of the drive part 11 is the amount of displacement of each position in the X-axis direction at the middle position in the Y-axis direction of the drive part 11, and the amount of displacement of the support part 13 is the amount of displacement of each position in the X-axis direction at the middle position in the Y-axis direction of the support part 13.

In the examination in FIGS. 4A and 4B, the overall length in the X-axis direction of the support part 13 was set to 7789 μm, and the overall length in the X-axis direction of the drive part 11 was set to 1865 μm. In addition, the depth in the X-axis direction of each slit S1 was set to 846 μm. The deepest position in the X-axis direction of each slit S1 corresponds to the position in the X-axis direction of an inflection point of the support part 13 described later.

First, referring to FIG. 4B, in the comparative example, the gradient of the waveform showing the displacement of the support part 13 switches between increasing and decreasing with positions P1 and P2 as boundaries. That is, on the left side of the position P1, the waveform of the support part 13 has a shape that is convex upward, and on the right side of the position P1, the waveform of the support part 13 has a shape that is convex downward. On the left side of the position P2, the waveform of the support part 13 has a shape that is convex upward, and on the right side of the position P2, the waveform of the support part 13 has a shape that is convex downward. Meanwhile, in the comparative example, the gradient of the waveform showing the displacement of the drive part 11 is either increasing or decreasing. That is, the waveform of the drive part 11 on the left side has a shape that is convex upward over the entire range, and the waveform of the drive part 11 on the right side has a shape that is convex downward over the entire range.

Therefore, in the comparative example, in ranges W1 and W2 in FIG. 4B, the curving directions of the drive part 11 and the support part 13 are opposite to each other. That is, in the range W1, the drive part 11 is curved convexly upward, but the support part 13 is curved convexly downward. In the range W2, the drive part 11 is curved convexly downward, but the support part 13 is curved convexly upward. As shown in FIG. 2B, in the comparative example, in the ranges W1 and W2, the boundaries of each drive part 11 and each support part 13 are connected to each other. Therefore, in the ranges W1 and W2, the curving of the support part 13 is inhibited by the opposite curving on the drive part 11 side. As a result, in the comparative example, the support part 13 is not efficiently driven by the driving force of the drive part 11, so that the driving efficiency of the movable part 14 is decreased.

On the other hand, in the configuration of the embodiment, as shown in FIG. 2A, the slits S1 are formed in the ranges W1 and W2, whereby each drive part 11 and each support part 13 are separated from each other. Therefore, in the configuration of the embodiment, in the ranges W1 and W2, the curving of the support part 13 is not inhibited by the opposite curving on the drive part 11 side. Accordingly, in the embodiment, as shown in FIG. 4A, the waveform of the support part 13 and the waveform of the drive part 11 are widely separated from each other. In addition, the driving force generated in the portion of the drive part 11 interposed between the two slits S1 is transmitted from the drive part 11 to the support part 13 via the connection position other than the slits S1. Therefore, in the configuration of the embodiment, the support part 13 can be more efficiently driven by the driving force of the drive part 11, so that the driving efficiency of the movable part 14 can be increased.

Next, the inventor examined the relationship between the depth of each slit S1 in the X-axis direction and the driving efficiency of the movable part 14 by simulation.

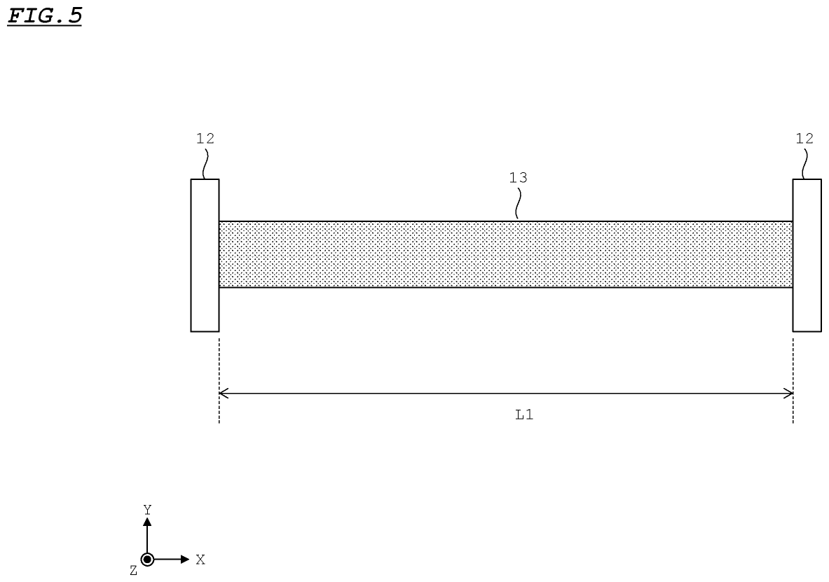

First, the inventor obtained an inflection point at which the gradient of the support part 13 which is curved when the movable part 14 is driven switches between increasing and decreasing, by simulation. Here, as shown in FIG. 5, the above inflection point was obtained for the support part 13 having a constant width in the Y-axis direction and a length of L1. The length L1 was set to 7789 μm as in the examination in FIGS. 4A and 4B. Under these conditions, the distribution of displacement in the Z-axis direction in a vibration mode that generates a gradient in a center portion of the support part 13 (secondary vibration mode when both ends are fixed) was analyzed.

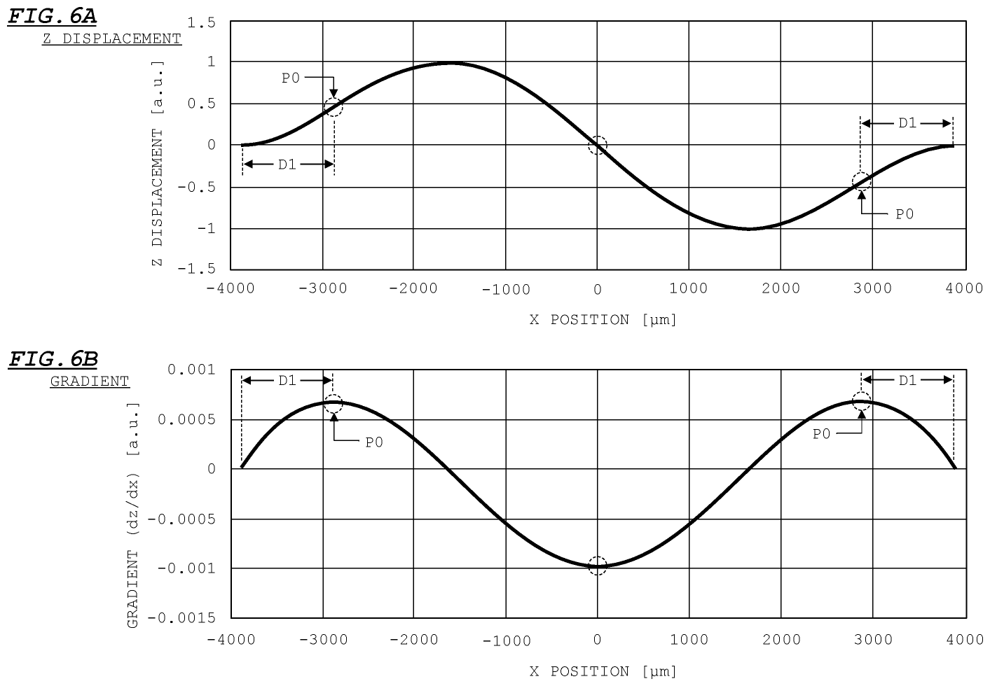

FIG. 6A is a graph showing a simulation result of the displacement distribution of the support part 13 in the vibration direction (Z-axis direction). FIG. 6B is a graph showing the gradient of a waveform of the displacement distribution obtained by differentiating the graph in FIG. 6A.

In FIGS. 6A and 6B, the horizontal axis shows the position in the X-axis direction (separation distance from the rotation axis R0) in the case where the middle position of the support part 13 in the X-axis direction is defined as 0. Here, a position in the X-axis positive direction is indicated by a positive value, and a position in the X-axis negative direction is indicated by a negative value. In FIG. 6A, the vertical axis shows the amount of displacement in the Z-axis direction in the case where the position of the support part 13 when not curved (in a horizontal state) is defined as 0, and in FIG. 6B, the vertical axis shows the gradient of the waveform in FIG. 6A. In each of FIGS. 6A and 6B, the vertical axis is normalized by a predetermined value.

In FIGS. 6A and 6B, the positions of dashed circles are inflection points. At each of these positions, the gradient of the amplitude waveform of the support part 13 switches between increasing and decreasing. In this simulation result, a distance D1 from each end of the support part 13 to each inflection point P0 was 1019 μm. As described above, in the examination in FIG. 4A, the deepest position of each slit S1 is set at the position of the inflection point P0 in the X-axis direction.

After obtaining the inflection points P0 as described above, the inventor obtained the relationship between the depth of each slit S1 in the X-axis direction and the driving efficiency of the movable part 14 by simulation.

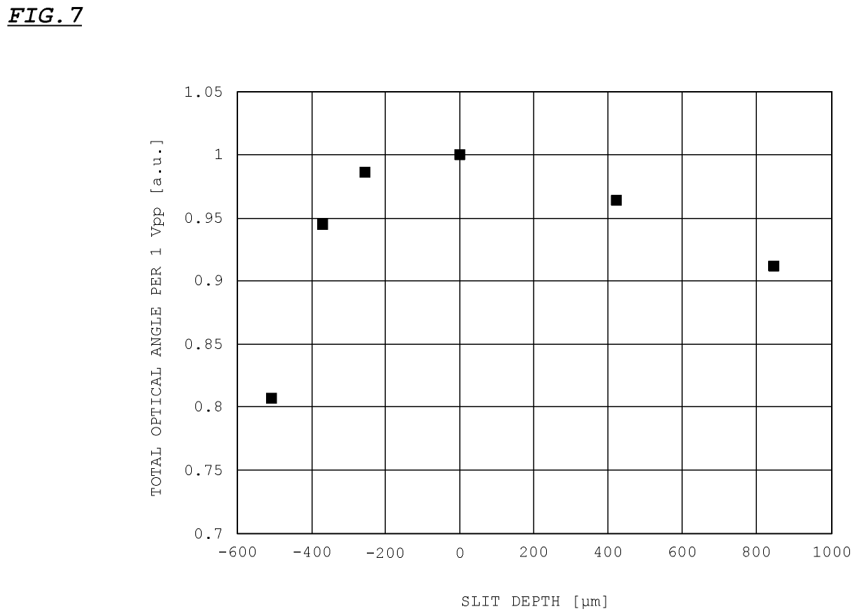

FIG. 7 shows a simulation result showing the relationship between the depth of each slit S1 and the driving efficiency of the movable part 14.

In FIG. 7, on the horizontal axis, the depth of the slit S1 is defined with the depth of the slit S1 as 0 in the case where the slit S1 extends to the inflection point P0 obtained in FIGS. 6A and 6B. A positive value on the horizontal axis indicates a value at which the depth of the slit S1 decreases, and a negative value on the horizontal axis indicates a value at which the depth of the slit S1 increases. In FIG. 7, on the vertical axis, the total of the deflection angle of the movable part 14 (reflection surface 20) per 1 Vpp is indicated by a value normalized by the maximum value of the simulation result.

In this simulation, in the configuration in FIG. 2A, the length in the X-axis direction of each support part 13 was set to 7789 μm, and the width in the X-axis direction of each drive part 11 in the region other than the slits S1 was set to 1865 μm. Under these conditions, the depth (length in the X-axis direction) of each slit S1 was changed, and the driving efficiency of the movable part 14 and the reflection surface 20 was obtained.

Here, the depth of the slit S1 (the value on the horizontal axis in FIG. 7) was changed to six types: −510 μm, −369 μm, −255 μm, 0 μm, 423 μm, and 846 μm. The plot at 846 μm on the horizontal axis corresponds to the case where the depth of the slit S1 is 0, that is, no slit S1 is formed as in the comparative example in FIG. 2B. The depth of the slit S1 in the case where the value on the horizontal axis is 0, that is, in the case where the slit S1 extends to the inflection point P0, is 846 μm.

As shown in FIG. 7, the driving efficiency of the movable part 14 gradually increased as the slit S1 became deeper. When the deepest position of the slit S1 corresponded to the position of the inflection point P0, the driving efficiency of the movable part 14 became the highest, and then the driving efficiency of the movable part 14 decreased as the slit S1 became deeper. When the depth of the slit S1 is excessively large as in the leftmost plot in FIG. 7, the driving efficiency of the movable part 14 became lower than that in the case where no slit S1 was provided (rightmost plot). Accordingly, it is confirmed that the depth of the slit S1 has a range suitable for improving the driving efficiency.

That is, in the examinaiton result in FIG. 7, it is confirmed that at least in the range to the depth corresponding to the second plot from the left, the driving efficiency of the movable part 14 becomes higher than that in the case where there is no slit S1. The depth (length in the X-axis direction) of the slit S1 corresponding to the second plot from the left is a depth extended by 369 μm from 864 μm, which is the depth of the slit S1 in the case where the slit S1 is extended to the inflection point P0. Therefore, from this examinaiton result, it is found that by setting the depth of the slit S1 in a range further to the depth larger by 44% (369 μm/846 μm) than the depth to the inflection point P0, the driving efficiency of the movable part 14 can be made higher than that in the case where there is no slit S1. In addition, from the examinaiton result in FIG. 7, it is also found that within this range, the depth to the inflection point P0 can increase the driving efficiency of the movable part 14 the most.

Therefore, from this examinaiton result, the depth of the slit S1 in the X-axis direction is preferably set within a range having, as an upper limit, a depth larger by about 40% than the depth to the inflection point P0, and is more preferably set to around the depth to the inflection point P0. Accordingly, the driving efficiency of the movable part 14 can be increased, and deflection of and scanning with light can be performed at a higher deflection angle by the reflection surface 20.

### Effects of Embodiment

According to the embodiment, the following effects can be achieved.

As shown in FIG. 1 and FIG. 2A, the pair of support parts 13 and the pair of drive parts 11 are separated from each other by the gaps (slits S1), and thus the curving of the support parts 13 at the positions of the gaps (slits S1) is not inhibited by the drive parts 11. In addition, the driving force of each drive part 11 generated around each gap (slit S1) is transmitted to the support part 13 via the connection range other than the gap (slit S1). Therefore, as shown in the examination result in FIG. 7, the support parts 13 can be more efficiently driven by the drive parts 11, so that the driving efficiency of the movable part 14 can be increased. As a result, the driving efficiency of the reflection surface 20 can be increased, so that deflection of and scanning with light can be performed at a higher deflection angle.

As shown in FIG. 1 and FIG. 2A, the gaps are formed between the pair of support parts 13 and the pair of drive parts 11 by forming the slits S1 in the alignment direction of the pair of drive parts 11 (X-axis direction) from the ends on the movable part 14 side of the pair of drive parts 11. Accordingly, the gaps can be formed continuously from the ends on the movable part 14 side of the pair of drive parts 11, so that the driving efficiency of the movable part 14 can be smoothly increased.

The depth of each slit S1 in the alignment direction of the pair of drive parts 11 (X-axis direction) is preferably set within a range having, as an upper limit, a depth larger by about 40% than the depth to the inflection point P0 at which the gradient of the waveform (gradient of the displacement in the thickness direction) of the support part 13 which is curved when the movable part 14 is driven switches between increasing and decreasing. Accordingly, as shown in the examination result in FIG. 7, the driving efficiency of the movable part 14 can be effectively made higher than that in the case where there is no gap (slit S1).

The depth of each slit S1 in the alignment direction of the pair of drive parts 11 (X-axis direction) is further preferably set to around the depth to the inflection point. Accordingly, as shown in the examination result in FIG. 7, the driving efficiency of the movable part 14 can be further effectively increased.

As shown in FIG. 1 and FIG. 2A, each drive part 11 includes the piezoelectric driver 11a as a drive source. Accordingly, the movable part 14 can be driven with high driving efficiency.

<Modifications>

In the above embodiment, the gap is formed between each drive part 11 and each support part 13 by continuously forming the slit S1 having a constant width in the Y-axis direction, but the method for forming the gap is not limited thereto. For example, the width in the Y-axis direction of the gap may be changed depending on the position in the X-axis direction by changing the width of the drive part 11 or the support part 13 in the X-axis direction. The gap does not have to be continuous in the X-axis direction, and may be formed intermittently in the X-axis direction. However, in order to further increase the driving efficiency of the movable part 14, it is preferable that the gap is formed continuously in the X-axis direction from the end on the movable part 14 side of the drive part 11 as in the above embodiment.

The shape of the drive element 1 in a plan view and the dimensions of each part of the drive element 1 are also not limited to those shown in the above embodiment, and can be changed as appropriate. The shape and the size of each piezoelectric driver 11a in a plan view can also be changed as appropriate. In addition, the thickness, the length, the width, and the shape of each fixing part 12 can also be changed as appropriate. For example, the thickness of each fixing part 12 may be equal to the thicknesses of each drive part 11 and each support part 13. The thickness, the width, and the shape of each fixing part 12 can be changed as appropriate as long as the drive element 1 can be installed on the installation surface.

In the above embodiment, both ends of the pair of support parts 13 are connected to the pair of fixing parts 12, but both ends of the support parts 13 do not have to be connected to the fixing parts 12. For example, the width in the Y-axis direction of each fixing part 12 may be set to be equal to the width in the Y-axis direction of each drive part 11, and both end portions of the support parts 13 may be connected to only both edges in the Y-axis direction of the drive parts 11. In this case as well, the driving efficiency of the movable part 14 can be increased by providing gaps (slits S1) between the support parts 13 and the drive parts 11. In addition, in the configuration in FIG. 1, both ends in the Y-axis direction of fixing parts 12 may be further connected in the X-axis direction to form a fixing part. That is, a fixing part 12 may be formed so as to surround the pair of drive parts 11 and the pair of support parts 13 in a plan view.

The drive element 1 may be used as an element other than the light deflection element 2. In the case where the drive element 1 is used as an element other than the light deflection element 2, the reflection surface 20 does not have to be placed on the movable part 14, and a member other than the reflection surface 20 may be placed thereon.

In addition to the above, various modifications can be made as appropriate to the embodiment of the present invention, without departing from the scope of the technological idea defined by the claims.

What is claimed is:

1. A drive element comprising:
a pair of drive parts placed so as to be aligned in one direction;
a movable part placed between the pair of drive parts;
a pair of support parts placed such that the pair of drive parts and the movable part are interposed therebetween;
a pair of connection parts connecting the pair of support parts to the movable part; and
a fixing part connected to at least each of the pair of drive parts in an alignment direction of the pair of drive parts, wherein
both end portions of the pair of support parts are connected to the pair of drive parts, respectively, and
gaps each having a predetermined length are provided between the pair of support parts and the pair of drive parts so as to extend in the alignment direction of the pair of drive parts.

2. The drive element according to claim 1, wherein the gaps are provided by forming slits in the alignment direction of the pair of drive parts from ends on the movable part side of the pair of drive parts.

3. The drive element according to claim 2, wherein a depth of each of the slits in the alignment direction of the pair of drive parts is set within a range having, as an upper limit, a depth larger by about 40% than a depth to an inflection point at which a gradient of displacement in a thickness direction of the support part which is curved when the movable part is driven switches between increasing and decreasing.

4. The drive element according to claim 3, wherein the depth of each of the slits is set to around the depth to the inflection point.

5. The drive element according to claim 1, wherein each of the drive parts includes a piezoelectric driver as a drive source.

6. A light deflection element comprising:
a drive element including
a pair of drive parts placed so as to be aligned in one direction,
a movable part placed between the pair of drive parts,
a pair of support parts placed such that the pair of drive parts and the movable part are interposed therebetween,
a pair of connection parts connecting the pair of support parts to the movable part, and
a fixing part connected to at least each of the pair of drive parts in an alignment direction of the pair of drive parts, and
a reflection surface located on the movable part, wherein
both end portions of the pair of support parts are connected to the pair of drive parts, respectively, and
gaps each having a predetermined length are provided between the pair of support parts and the pair of drive parts so as to extend in the alignment direction of the pair of drive parts.

7. The light deflection element according to claim 6, wherein the gaps are provided by forming slits in the alignment direction of the pair of drive parts from ends on the movable part side of the pair of drive parts.

8. The light deflection element according to claim 7, wherein a depth of each of the slits in the alignment direction of the pair of drive parts is set within a range having, as an upper limit, a depth larger by about 40% than a depth to an inflection point at which a gradient of displacement in a thickness direction of the support part which is curved when the movable part is driven switches between increasing and decreasing.

9. The light deflection element according to claim 8, wherein the depth of each of the slits is set to around the depth to the inflection point.

10. The light deflection element according to claim 6, wherein each of the drive parts includes a piezoelectric driver as a drive source.
